(19) United States
(12) Patent Application Publication
(10) Pub. No.: US 2010/0117190 A1
(43) Pub. Date: May 13, 2010

(54) FUSE STRUCTURE FOR INTERGRATED CIRCUIT DEVICES

(76) Inventors: Harry CHUANG, Austin (SG); Kong-Beng Thei, Hsinchu (TW); Sheng-Chen Chung, Hsinchu (TW); Mong-Song Liang, Hsinchu (TW)

Correspondence Address: BIRCH, STEWART, KOLASCH & BIRCH, LLP, P.O. BOX 747, FALLS CHURCH, VA, 22040-0747, US

(21) Appl. No.: 12/270,717

(22) Filed: Nov. 13, 2008

(51) Int. Cl. H01L 21/768; H01L 23/525

(52) U.S. Cl. 257/529; 438/601; 257/E23.149; 257/E21.592

(57) ABSTRACT

A fuse structure for an IC device and methods of fabricating the structure are provided. The fuse structure comprises a metal-containing conductive strip formed over a portion of a semiconductor substrate. A dielectric layer is formed over the semiconductor substrate, covering the conductive strip. A first interconnect and a second interconnect are formed in vias extending through the dielectric layer, each physically and electrically connecting to a part of the conductive layer. First and second wiring structures are formed over the dielectric layer in electrical contact with the first and second interconnects respectively. The contact area between one of the interconnects and the strip is chosen so that electromigration will occur when a pre-selected current is applied to the fuse structure.

### BACKGROUND OF THE INVENTION

1. Field of the Invention

The invention relates to integrated circuit (IC) devices, and more particularly to fuse structures used in IC devices.

2. Description of the Related Art

Many integrated circuits (ICs) such as dynamic random access memory (DRAM) and static random access memory (SRAM) employ fuses. The fuses provide connections to redundant circuit elements that can replace circuit elements with manufacturing defects in order to maintain the functionality of the entire integrated circuit. Moreover, fuses can also make it possible for a device manufacturer to select product options, such as voltage options, packaging pin out options, so that one basic product design can be used for several different end products.

In general, two types of fuse are in use today. In one type, the fuse element is blown using an external heat source, e.g., a laser beam. In a second type, an electrical current is flowed through the fuse element to blow the fuse. The later type, electrical fuses (E-fuses), are preferred because the fuse blow operation can be automated in conjunction with a circuit test.

FIGS. 1-3 illustrate a conventional electrical fuse that can be selectively blown, or programmed, by using an electrical current. FIGS. 1 and 2 illustrate a top plan view and a cross-section, respectively, of a portion of an integrated circuit 10 comprising an intact, or not blown, fuse structure 15. As shown in FIG. 1, the fuse structure 15 is formed over an insulation layer 20 and comprises two contacts 30 in electrical contact with a conductive silicide layer 40. As shown in FIG. 2, the silicide layer 40 is disposed over a polysilicon layer 50. The silicide layer 40 and the polysilicon layer 50 are generally arranged in a stack 55 residing over the insulation layer 20. Typically, the insulation layer 20 is an oxide layer deposited or grown on a semiconductor substrate 60, which can be, for example, monocrystalline silicon. Furthermore, the fuse structure 15 is generally covered with an insulation layer 70 to electrically isolate the fuse structure 15 from other devices (not shown) formed over the semiconductor substrate 60.

During programming and operation of the conventional fuse structure 15 shown in FIGS. 1 and 2, electrical current flowing through the fuse structure 15 generally proceeds from one contact 30A, through the silicide layer 40, to the other contact 30B. While current is increased to a level that exceeds a predetermined threshold current of the fuse structure 15, the silicide layer 40 will change its state, for example, by melting, thereby altering a resistance of the structure. Note that depending on the sensitivity of the sensing circuitry (e.g., a sense amp), a fuse may be considered “blown” if a change in resistance is only modest. Therefore the term “blowing” a fuse may be considered to broadly cover a modest alteration of the resistance or the creation of a complete open circuit. FIG. 3 illustrates a cross section of the fuse structure 15 shown in FIG. 2 after the fuse structure 15 has been programmed (i.e. blown). A programming current blows a conventional fuse structure 15 by effectively melting or otherwise altering a state of the silicide layer 40 in a region 75, thereby forming discontinuity 85 in the silicide layer and agglomerations 80 on either side of the discontinuity 85 in the silicide layer 40.

The insulating layer 20, the polysilicon layer 50 and the silicide layer 40 of the fuse structure 15 shown in FIGS. 1-3 are typically fabricated on the semiconductor substrate 60 during the fabrication of a gate structure of a metal oxide semiconductor (MOS) transistor (not shown), so that the fabrication of the fuse structure does not add any steps to the overall manufacturing process.

However, as device densities continue to increase, polysilicon gates are increasingly adversely affected by poly depletion. Since metal gates do not suffer from poly depletion, there has been much interest in replacing the polysilicon gate with a metal-containing gate to overcome the problems associated with the poly depletion. Several refractory metals and their nitride such as Ti, W and Ta have been demonstrated as desirable components of a metal-containing gate electrode in a MOS device.

Replacement of the conventional polysilicon gate by a metal-containing gate means that a metal layer must replace the silicide layer 40 in the fuse structure 15 if the fabrication of the fuse structure 15 is to be integrated into the manufacturing process. Metal-containing fuses that can be formed during the same manufacturing step as a metal-containing gate can not be blown by means of an electrical current causing agglomerations, which is the means of electrically blowing a conventional fuse structure 15 comprising a conductive silicide layer 40. Thus, programming metal-containing fuses can be problematic.

### BRIEF SUMMARY OF THE INVENTION

Therefore, what is needed in the art is a reliable fuse structure that can be fabricated without additional process steps, and that can be programmed using an electrical current.

In accordance with an exemplary embodiment of the invention, a fuse structure comprises a strip of a metal-containing conductive material disposed over a portion of a semiconductor substrate, wherein the strip extends along a first direction and has a uniform line width. A dielectric layer covers the conductive layer. Within die dielectric there are a first via and a second via, containing a first interconnect and a second interconnect respectively. The first interconnect is in physical and electrical contact with a first location on the strip, while the second interconnect is in physical and electrical contact with a second location on the strip. The first and second locations on the conductive strip do not contain silicon. Overlying the dielectric are a first wiring structure electrically connected to the first interconnect and a second wiring structure electrically connected to the second interconnect.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 illustrates a plan view of a conventional fuse structure;

FIG. 2 illustrates a cross-section view along line 2-2 in FIG. 1;

FIG. 3 illustrates the cross-section shown in FIG. 2 after the conventional fuse structure has been programmed;

FIG. 4 illustrates a plan view of an exemplary fuse structure according to an embodiment of the present invention;

FIG. 5 illustrates a cross-section view along line 5-5 in FIG. 4;

FIGS. 6 and 7 illustrate the cross-section shown in FIG. 5 after the exemplary fuse structure has been programmed;

FIGS. 8a and 8b illustrate plan views of alternative embodiments of interconnect 108B;

FIG. 9 illustrates a plan view of an exemplary fuse structure according to another exemplary embodiment of the present invention;

FIG. 10 illustrates a plan view of an exemplary fuse structure according to yet another embodiment of the present invention;

FIG. 11 illustrates a cross-section view along line 5-5 in FIG. 10;

FIG. 12 illustrates a plan view of an exemplary fuse structure according to another exemplary embodiment of the present invention;

FIG. 13 illustrates a cross-section view along line 5-5 of FIG. 4 of an alternative embodiment of a fuse structure in accordance with the invention;

FIG. 14 illustrates a cross-section view along line 5-5 of FIG. 4 of an alternative embodiment of a fuse structure in accordance with the invention.

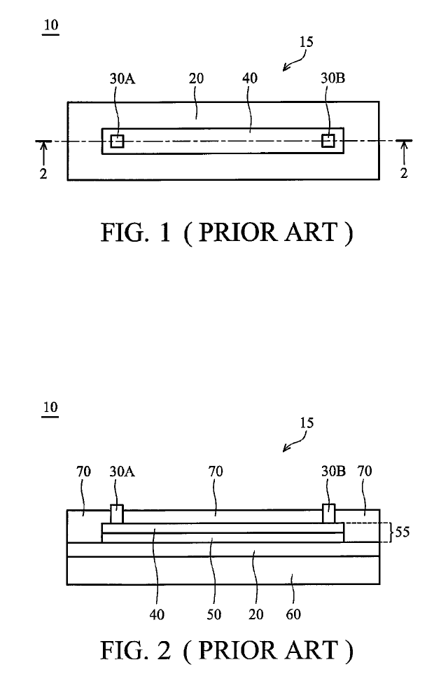

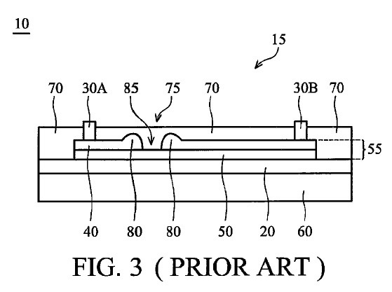

### DETAILED DESCRIPTION OF THE INVENTION

This description is made for the purpose of illustrating the general principles of the invention and should not be taken in a limiting sense. The scope of the invention is best determined by reference to the appended claims.

The invention is directed toward a metal-containing fuse and a method for forming thereof over a semiconductor substrate. Metal-containing fuses in accordance with the invention can be utilized within integrated circuits (ICs) for a variety of applications, such as for redundancy in memory circuits and for customization schemes wherein a generic semiconductor chip can be utilized for several differing applications, dependent upon the programming of a predetermined set of fuses integrated into the IC.

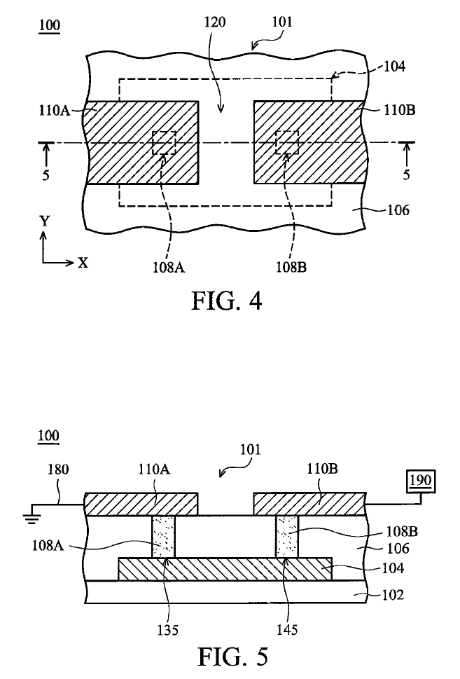

FIGS. 4 and 5 illustrate a plan view and cross-sectional view, respectively, of a portion of an integrated circuit 100 comprising an exemplary fuse structure 101. The fuse structure is formed over a semiconductor substrate 102, which is typically a wafer of single-crystalline silicon. It will be understood by one of ordinary skill in the art that in some embodiments of the invention various layers (not shown), such as an insulating layer or even multiple layers forming a device, may be interposed between the fuse structure 101 and the semiconductor substrate 102. For example, the fuse structure 101 can be formed over a gate oxide (not shown) that electrically and thermally insulates the fuse structure 101 from any underlying structures (not shown).

The fuse structure 101 comprises a strip of a metal-containing conductive material 104. The strip 104 is covered by a dielectric layer 106. The fuse structure 101 further comprises a first interconnect 108A that extends through a via in the dielectric layer 106 and is in physical and electrical contact with the strip 104. The area of contact between the lower surface of the first interconnect 108A, and the topmost surface of the strip 104 defines a first interface 135. The fuse structure 101 also comprises a second interconnect 108B that extends through a via in the dielectric layer 106 and is in physical and electrical contact with the strip 104. The area of contact between the lower surface of the second interconnect 108B and the topmost surface of the strip 104 defines a second interface 145. The portion of the metal-containing layer 104 between the first interface 135 and the second interface 145 generally defines a fuse region 120 of the strip 104. The end of the first interconnect 108A opposite the end connected to the strip 104 is electrically connected to a first wiring structure 110A. Similarly, the end of the second interconnect 108B not connected to the strip 104 is connected to a second wiring structure 110B. The dielectric layer 106 electrically isolates the first and second wiring structures 110A, 110B from the underlying strip 104, and also isolates the first and second interconnects 108A,108B from each other. In the embodiment shown in FIG. 5, the first wiring structure 110A electrically connects one end of the strip 104 to an electrical ground 180, while the second wiring structure electrically connects the opposite end of the strip 104 to a power source 190. In alternative embodiments, the wiring structures 110A and 110B could connect the fuse structure 101 to other IC components or devices (not shown).

The metal-containing conductive strip 104, along with the first interconnect 108A and the second interconnect 108B, may comprise metals such as tungsten (W), aluminum (Al), silver (Ag), gold (Au), or alloys thereof. The metal-containing conductive strip 104 can comprise a single metal-containing layer, or the strip 104 may comprise a laminate of a plurality of stacked metal-containing sub-layers and a topmost layer. It is preferable that the surface of the strip 104 contacting the first and second interconnects 108A, 108B not contain silicon, so the topmost layer of a laminated strip 104 is preferably silicon-free. Similarly if the strip 104 comprises a single layer instead of a laminate then the material forming that layer should be silicon-free. Furthermore, the first and second interconnects 108A, 108B may further comprise a barrier metal (not shown), such as titanium nitride (TiN), interposed between the interconnects 108A,108B and both of the strip 104 and the dielectric 106. The dielectric layer 106 comprises, for example, an inter-level dielectric (ILD) layer made up of material such as phosphosilicate glass (PSG), undoped phosphosilicate glass (USG), borophosphosilicate glass (BPSG), organosilicate glass (OSG), or silicon dioxide. The wiring structures 110A and 110B may comprises the metals employed in standard metallization processes such as aluminum or copper. The embodiment shown in FIG. 5 comprises aluminum wiring structures 110A, 110B formed using standard metallization processes.

As shown in shown in FIG. 4, the strip 104 and the wiring structures 110A, 110B have a substantially uniform line width along their lengths, all of which extend along the X-direction indicated in FIG. 4. The strip 104 and the wiring structures 110A, 110B also substantially parallel in that they all extend along a direction parallel to the X-direction indicated in FIG. 4. In other words, the longitudinal axes of the wiring structures 110A, 110B and the strip 104 are parallel.

In the exemplary fuse structure 101, the first interface 135 and the second interface 145 are formed so that they have similar areas. The area of the interfaces 135,145 is chosen to be small enough so that a current applied to the fuse structure 101 by power supply 190 will create a large enough current density at the second interface 145 to create electromigration (EM) at the second interface 145. The electromigration will electrically disconnect the second interconnect 108B from the strip 104, thus blowing the fuse structure 101. In a typical application of a fuse structure 101 in accordance with the invention it may be desirable to employ a standard power supply that applies a pre-selected voltage or current. Once the current to be applied to the fuse structure 101 is selected, one skilled in the art can determine what the areas of the interfaces 135,145 must be in order for electromigration to occur. The exact interface areas will depend not only on the pre-selected current, but on the materials forming the second interconnect 108B and the strip 104.

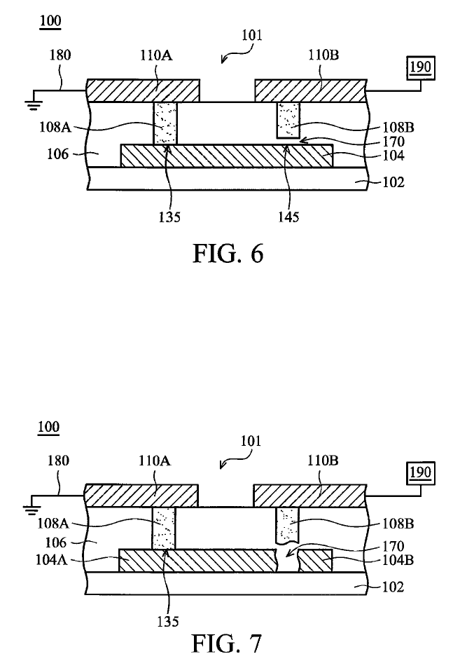

Two possible methods by which electromigration may disconnect the second interconnect 108B from the strip 104 are shown in FIGS. 6 and 7. In FIG. 6 the electromigration disrupts the second interface 145, creating a gap 170 between the second interconnect 108B and the strip 104. In FIG. 7 the second interconnect 108B is also disconnected from the strip 104, but the electromigration also opens a gap 170 in the strip 104, separating the strip 104 into two portions 104A and 104B. In an exemplary embodiment, the second interface 145 has an area of about 1−1×10⁻⁴ μm². To program the exemplary embodiment of the fuse structure 101, a voltage (not shown) of about 0.5-5.0 V is applied across the fuse structure 101 by the power source 190, forming a first current density of about 0.1-100 A/um² in the second interface 145. Since the specified current densities are great enough to cause electromigration (EM) at the second interface 145, the fuse structure is thus blown.

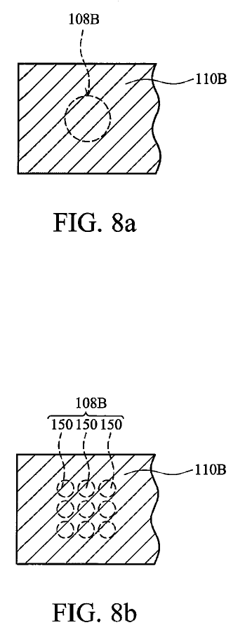

The interconnects 108A,108B in FIG. 4 are shown as having a square cross-section, but in other embodiments the cross-section of the interconnects 108A, 108B could be other shapes. As recognized by those skilled in the art, the most important criteria in implementing various embodiments of the invention is the cross-sectional area of the interconnects 108A, 108B, which defines the area of the second interface 145, which must have a small enough area so that the current applied to the fuse structure 101 creates a high enough current density at the second interface 145 to create electromigration. In the embodiment shown in FIG. 8a, the second interconnect 108B has a circular cross-section. In FIG. 8b, the second interconnect 108B comprises a plug comprising an array of a plurality of sub-plugs 150. The sub-plugs 150 can have diameters of about 0.2-0.01 μm and can be arranged with a pitch of about 0.5-0.02 μm therebetween. FIG. 9 illustrates a plan view of a portion of an embodiment of the fuse structure 101 in which the cross-section of the interconnects 108A, 108B is substantially rectangular.

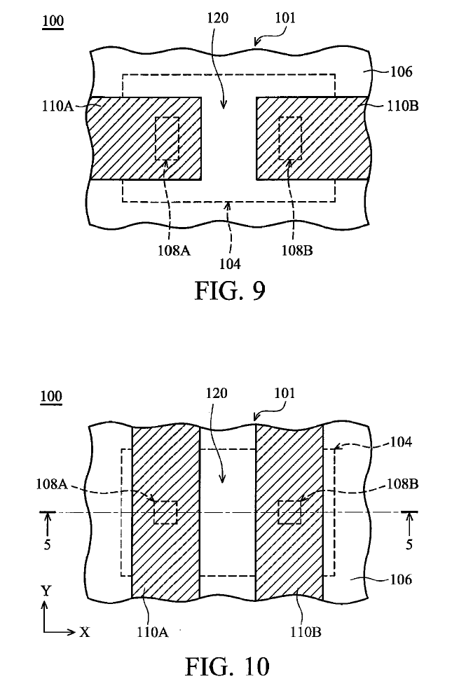

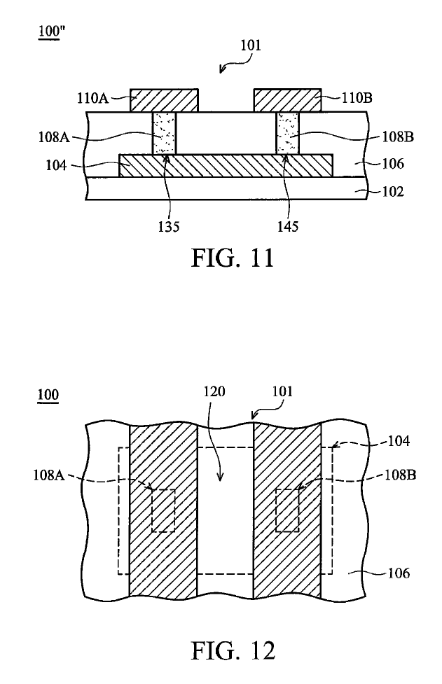

FIGS. 10 and 11 illustrate a plan view and cross-sectional view, respectively, of an embodiment in which the fuse structure 101 comprises wiring structures 110A, 110B that extend along a direction perpendicular to the direction along which the strip 104 extends. In other words, the longitudinal axes of the wiring structures 110A, 10B and the strip 104 are perpendicular. In terms of the coordinate system shown in FIG. 10, the wiring structures 100A, 110B are parallel to the Y-axis, while the strip 104 is parallel to the X-axis. Just as in the embodiment shown in FIG. 4, the wiring structures 110A, 110B can be formed over the dielectric layer 106 using standard aluminum metallization processes. The portion of the fuse structure 101 in FIGS. 10 and 11 underneath the wiring structures 110A, 110B is identical to the previously described fuse structure 101 in FIGS. 4 and 5. A variation of the embodiment in FIGS. 10 and 11 in which the interconnects 108A, 108B have substantially rectangular cross-sections.

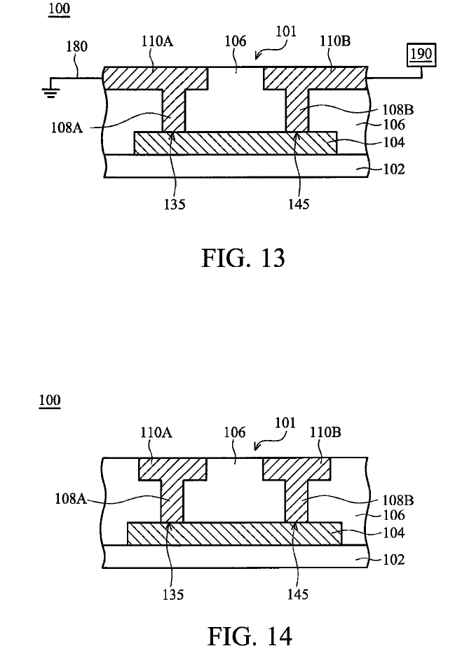

The wiring structures 110A, 110B in the embodiments shown in FIGS. 5 and 11 can be fabricated using standard aluminum metallization processes. In alternative embodiments of the invention, the wiring structures 110A, 110B may comprise copper or copper-alloys and may be fabricated using damascene or dual-damascene processes. FIG. 13 shows a cross-sectional view of the embodiment of FIG. 4 in which the wiring structures 110A, 110B and the interconnects 108A, 108B comprise copper and have been fabricated using a dual damascene process. Furthermore, the first interconnect 108A and the second interconnect 108B further comprise a barrier metal (not shown) such as titanium nitride interposed between the interconnects 108A, 108B and the strip 104, between the interconnect 108A, 108B and the dielectric 106, and between the wiring structures 110A, 110B and the dielectric 106. When copper-containing materials are used for the interconnects 108A, 108B and the wiring structures 110A, 110B, the other components of the fuse structure 101, such as the substrate 102, the strip 104, and the dielectric 106, can still be fabricated from the same materials used in the embodiment of FIG. 5. Specifically, the strip 104 can comprise metal-containing materials such as tungsten (W), aluminum (Al), silver (Ag), gold (Au), or alloys thereof and can be formed with a single metal-containing layer of a laminated layer including a plurality of stacked metal-containing sub-layers. Preferably, the top surface of the patterned metal-containing layer 104 is preferably silicon-free. The dielectric layer 106 may comprise, for example, an inter-level dielectric (ILD) layer made up of a material such as phosphosilicate glass (PSG), undoped phosphosilicate glass (USG), borophosphosilicate glass (BPSG), organosilicate glass (OSG), or silicon dioxide. Just as in the embodiment shown in FIG. 5, it will be understood by one of ordinary skill in the art that in the embodiment shown in FIG. 13 various layers (not shown), such as an insulating layer or even multiple layers forming a device, may be interposed between the fuse structure 101 and the semiconductor substrate 102. For example, the fuse structure 101 can be formed over a gate oxide (not shown) that electrically and thermally insulates the fuse structure 101 from any underlying structures (not shown).

FIG. 14 shows a cross-sectional view of the embodiment of FIG. 10 in which the wiring structures 110A, 110B and the interconnects 108A,108B comprise copper and have been fabricated using a dual damascene process. As in the previously described embodiment of FIG. 13, the first interconnect 108A and the second interconnect 108B further comprise a barrier metal (not shown) such as titanium nitride that separates the interconnects from the strip 104 and the dielectric 106. The materials for the components of the fuse structure 101 other than the interconnects 108A, 108B and the wiring structures 11A, 110B can be selected in the same manner as for the embodiments in FIGS. 5 and 13.

The fuse structures 101 in all of the exemplary embodiments are all programmed in the same manner: a current is passed through the fuse structure 101 that creates a large enough current density high at the second interface 145 so that electromigration occurs at the interface. As would be understood by one skilled in the art, electromigration occurs when the current density reaches a high-enough level, and the current density at the second interface 145 is determined by the voltage applied across the fuse structure 101, the resistance of the fuse structure 101 (the current is related to the voltage and resistance by Ohm's law), and the area of the second interface 145 (current density=current/area). One of the advantages of the fuse structures illustrated above is that they can be fabricated during a process for forming a metal-containing gate structure or a process for forming interconnecting structures of an IC device, which means the fuse structures can be fabricated without additional process steps or masks. Compared with the “agglomeration” mechanism for programming the conventional silicide-containing fuse, the “electromigration” mechanism for programming the exemplary fuse structures described above has the advantages of a higher repairable rate, easier repair, reduced uncertainty and complexity, and allowing more flexible applications to be incorporated in IC device structures.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A fuse structure, comprising
a metal-containing conductive strip disposed over a portion of a semiconductor substrate, wherein the strip extends along a first direction and has a uniform line width;
a dielectric layer disposed over the semiconductor substrate that covers the strip;
a first interconnect and a second interconnect extending through the dielectric layer, each physically and electrically contacting a topmost surface of the strip, the first interconnect contacting the strip at a first interface and the second interconnect contacting the strip at a second interface;
a first wiring structure formed over the dielectric layer and in electrical contact with the first interconnect; and
a second wiring structure formed over the dielectric layer and in electrical contact with the second interconnect,
wherein the topmost surface of the strip comprises a silicon-free material, and wherein the area of the second interface is small enough so that an application of a pre-selected current creates electromigration at the second interface.

2. The fuse structure of claim 1, wherein the first and second wiring structures extend along a direction parallel to the direction along which the strip extends.

3. The fuse structure of claim 1, wherein the first and second wiring structures extend along a direction perpendicular to the direction along which strip extends.

4. The fuse structure of claim 1, wherein the area of the second interface is about 1−1×10⁻⁴ μm².

5. The fuse structure of claim 1, wherein the pre-selected current produces a current density at the second interface of about 0.1-100 A/um².

6. The fuse structure of claim 5, wherein the first wiring structure and the second wiring structure comprise copper.

7. The fuse structure as claimed in claim 1, wherein the strip comprises a metal selected from the group consisting of tungsten (W), aluminum (Al), silver (Ag), and gold (Au).

8. The fuse structure as claimed in claim 1, wherein the first interconnect and the second interconnect comprise a metal selected from the group consisting of tungsten (W), aluminum (Al), silver (Ag), and gold (Au).

8. The fuse structure as claimed in claim 1, wherein the first wiring structure and second wiring structure comprise aluminum.

9. The fuse structure as claimed in claim 1, wherein the first interconnect and the second interconnect comprise copper.

10. The fuse structure as claimed in claim 1, wherein the strip comprises a laminate.

11. A method of fabricating a fuse structure, the method comprising:
depositing a strip of a metal-containing conductive material over a portion of a semiconductor substrate, the strip extending along a first direction and having a uniform line width;
depositing a dielectric layer over the semiconductor substrate, covering the strip;
creating a first via and a second via in the dielectric layer that extends to a topmost surface of the strip;
depositing a conductive material in the first and second vias to form a first interconnect in the first via that contacts the topmost surface of the strip at a first interface and a second interconnect in the second via that contacts the topmost surface of the strip at a second interface; and
forming first and second wiring structures on top of the dielectric, wherein the first wiring structure is in electrical contact with the first interconnect and the second wiring structure is in electrical contact with the second interconnect,
wherein the topmost surface of the strip comprises a silicon-free conductive materials.

12. The method of claim 11, wherein the first interconnect and the second interconnect comprise a metal selected from the group consisting of tungsten (W), aluminum (Al), silver (Ag), and gold (Au).

13. The method of claim 11, wherein the strip comprises a metal selected from the group consisting of tungsten (W), aluminum (Al), silver (Ag), and gold (Au).

14. The method of claim 11, wherein the step of depositing a conductive material in the first and second vias comprises depositing a barrier layer.

15. The method of claim 11, wherein first interconnect and the second interconnect comprise copper.

16. The method of claim 15, wherein the steps of depositing a conductive material in the first and second vias and forming first and second wiring structures on top of the dielectric are carried by means of a dual damascene process.
